(19) United States
(12) Patent Application Publication
(10) Pub. No.: US 2025/0372478 A1
(43) Pub. Date: Dec. 4, 2025

(54) SEMICONDUCTOR DEVICE AND METHOD OF MANUFACTURING THE SEMICONDUCTOR DEVICE

(71) Applicant: SHINKO ELECTRIC INDUSTRIES CO., LTD., Nagano-shi (JP)

(72) Inventor: Yoichi Nishihara, Nagano (JP)

(21) Appl. No.: 19/215,532

(22) Filed: May 22, 2025

(30) Foreign Application Priority Data
May 28, 2024 (JP) 2024-086442

(51) Int. Cl. H01L 23/367; H01L 21/48; H01L 21/56; H01L 23/31

(52) U.S. Cl. CPC H01L 23/3675; H01L 21/4871; H01L 21/565; H01L 23/3142

(57) ABSTRACT

A semiconductor device includes an insulating base material that includes an adhesive layer on one of surfaces of the insulating base material; an electronic component that is fixed to the one of the surfaces; a metal plate that is arranged to sandwich the electronic component with the one of the surfaces; a sealing resin that is filled between the insulating base material and the metal plate; a wiring layer that is formed on another of the surfaces, and connected to the electronic component by way of a via; and a metal layer that is made of a same metal material as that used for the wiring layer and the via, and covers a surface of the metal plate located on a side opposite to a surface that is covered by the sealing resin.

### CROSS-REFERENCE TO RELATED APPLICATION

This application is based upon and claims the benefit of priority of the prior Japanese Patent Application No. 2024-086442, filed on May 28, 2024, the entire contents of which are incorporated herein by reference.

### FIELD

The embodiment discussed herein is related to a semiconductor device and a method of manufacturing the semiconductor device.

### BACKGROUND

Conventionally, there is a known semiconductor device having a structure in which, for example, an electronic component, such as a semiconductor element, is arranged on one of surfaces of an insulating base material by way of an adhesive layer, and a wiring layer is formed on the other of the surfaces of the insulating base material. In such a semiconductor device, the wiring layer is connected to the electronic component by way of a via that passes through the insulating base material and the adhesive layer. In this way, as a result of the wiring layer being connected to the electronic component by way of the via, heat generated from the electronic component is radiated to the outside by way of passing through the wiring layer and the via.

Furthermore, in order to increase a heat radiation path from the electronic component, in some cases, a metal plate functioning as a heat sink is arranged so as to sandwich the electronic component with the insulating base material, and the electronic component is bonded to the metal plate.
Patent Document 1: Japanese Laid-open Patent Publication No. 2008-198607

However, in the semiconductor device having the structure in which the electronic component is bonded to the metal plate, there is a problem in that it is difficult to sufficiently radiate heat generated from the electronic component. In other words, the thickness of the metal plate bonded to the electronic component is relatively thin, so that the heat generated from the electronic component is conducted in a thickness direction of the metal plate, and is then radiated to the outside. However, dispersion of heat in a surface direction of the metal plate (in the direction perpendicular to the thickness direction) is not sufficiently performed when compared to a case where heat is conducted in the thickness direction of the metal plate, so that the efficiency of heat radiation is not very high. As a result of this, in a case of an electronic component from which a relatively large amount of heat is generated, it is difficult to sufficiently radiate heat from the electronic component.

### SUMMARY

According to an aspect of an embodiment, a semiconductor device includes an insulating base material that includes an adhesive layer on one of surfaces of the insulating base material; an electronic component that is fixed to the one of the surfaces of the insulating base material by way of the adhesive layer; a metal plate that is arranged so as to sandwich the electronic component with the one of the surfaces of the insulating base material; a sealing resin that is filled between the insulating base material and the metal plate, and that covers the electronic component; a wiring layer that is formed on another of the surfaces of the insulating base material, and that is connected to the electronic component by way of a via that passes through the insulating base material and the adhesive layer; and a metal layer that is made of a same metal material as that used for the wiring layer and the via, and that covers a surface of the metal plate located on a side opposite to a surface that is covered by the sealing resin.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a semiconductor device according to an embodiment;

FIG. 2 is a flowchart illustrating a method of manufacturing the semiconductor device according to the embodiment;

FIG. 3 is a diagram illustrating a specific example of an insulating base material;

FIG. 4 is a diagram illustrating a specific example of an adhesive layer forming process;

FIG. 5 is a diagram illustrating a specific example of a via hole forming process;

FIG. 6 is a diagram illustrating a specific example of an electronic component fixing process;

FIG. 7 is a diagram illustrating a specific example of a seed layer forming process;

FIG. 8 is a diagram illustrating a specific example of an outer peripheral portion cutting process;

FIG. 9 is a diagram illustrating a specific example of a bonding process;

FIG. 10 is a diagram illustrating a specific example of a resin sealing process;

FIG. 11 is a diagram illustrating a specific example of an electrolytic copper plating process;

FIG. 12 is a diagram illustrating a specific example of a wiring layer forming process;

FIG. 13 is a diagram illustrating a specific example of a surface treatment layer forming process; and

FIG. 14 is a diagram illustrating implementation of the semiconductor device.

### DESCRIPTION OF EMBODIMENT

Preferred embodiment of a semiconductor device and a method of manufacturing the semiconductor device disclosed in the present invention will be described in detail below with reference to the accompanying drawings. Furthermore, the disclosed technology is not limited by the embodiment.

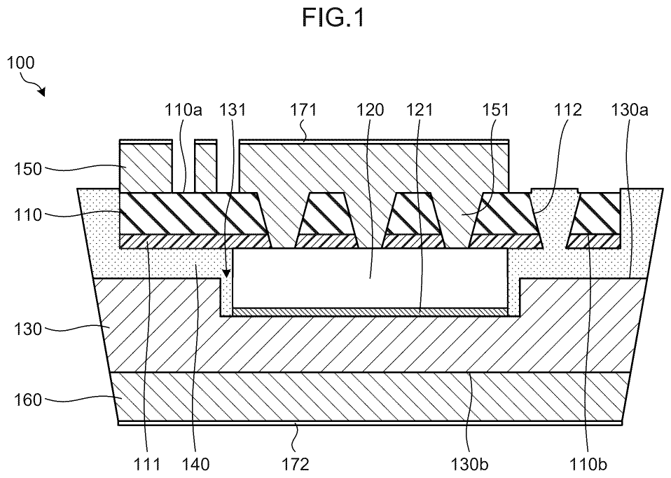

FIG. 1 is a diagram illustrating a configuration of a semiconductor device 100 according to an embodiment. In FIG. 1, a cross-sectional view of the semiconductor device 100 is schematically illustrated. Furthermore, in the description below, a surface closer to a mounting substrate when the semiconductor device 100 is mounted on the mounting substrate is referred to as a “lower surface”, whereas a surface away from the mounting substrate is referred to as an “upper surface”, and a vertical direction is defined based on this. However, the semiconductor device 100 may be manufactured and used by being inverted vertically, for example, or may be manufactured and used in an arbitrary posture.

The semiconductor device 100 illustrated in FIG. 1 includes an insulating base material 110 and a metal plate 130, and includes a sealing resin 140 that covers an electronic component 120 that is arranged by being sandwiched between a lower surface 110b (one example of one of the surfaces) of the insulating base material 110 and the metal plate 130. Furthermore, the semiconductor device 100 includes a wiring layer 150 that is formed on an upper surface 110a of the insulating base material 110 exposed from the sealing resin 140, and an electrolytic copper plating layer 160 (one example of a metal layer) that covers a lower surface 130b of the metal plate 130 exposed from the sealing resin 140.

The insulating base material 110 is a member in the form of a film, and includes an adhesive layer 111 below the lower surface 110b. The material used for the insulating base material 110 may be, for example, an insulation property resin, such as a polyimide-based resin, a polyethylene-based resin, or an epoxy-based resin. The thickness of the insulating base material 110 may be set to, for example, about 25 μm to 200 μm. The material used for the adhesive layer 111 may be, for example, a thermosetting resin, such as an epoxy-based resin, a polyimide-based resin, or a silicon-based resin. The thickness of the adhesive layer 111 may be set to, for example, about 10 μm to 60 μm. Furthermore, in the insulating base material 110 and the adhesive layer 111, a through-hole 112 that passes through the insulating base material 110 and the adhesive layer 111 in the thickness direction is arranged at a position that does not overlap with the wiring layer 150.

The electronic component 120 is an electronic component in which electronic circuits having various functions are integrated on a semiconductor. The electronic component 120 is fixed to the lower surface 110b of the insulating base material 110 by way of the adhesive layer 111.

The electronic component 120 used may be, for example, a semiconductor element constituted by using silicon (Si) or silicon carbide (Sic). Furthermore, the electronic component 120 may also be a semiconductor element constituted by using gallium nitride (GaN), gallium arsenide (GaAs), or the like. For example, the electronic component 120 used may be a semiconductor element (for example, a silicon chip for a CPU or the like), an Insulated Gate Bipolar Transistor (IGBT), a Metal-Oxide-Semiconductor Field-Effect Transistor (MOSFET), diode, or the like functioning as an active element.

The metal plate 130 is arranged by sandwiching the electronic component 120 with the lower surface 110b of the insulating base material 110. The metal plate 130 is bonded to the electronic component 120 that is fixed to the lower surface 110b of the insulating base material 110. The metal plate 130 absorbs heat generated from the electronic component 120, and radiates the heat to the outside by way of the electrolytic copper plating layer 160. The material used for the metal plate 130 may be, for example, copper or a copper alloy. The thickness of the metal plate 130 may be set to, for example, about 100 μm to 2000 μm.

The metal plate 130 is bonded to the electronic component 120 on an upper surface 130a. On the upper surface 130a of the metal plate 130, a recess portion 131 may be formed at a position corresponding to a position of the electronic component 120. In such a case, the electronic component 120 is accommodated in the recess portion 131, and is bonded to the bottom surface of the recess portion 131 by way of, for example, a conductive bonding member 121 constituted by using solder paste, or the like.

As a result of the recess portion 131 being formed on the upper surface 130a of the metal plate 130, an excessive spread of an area of the conductive bonding member 121 is controlled. Furthermore, the electronic component 120 that is fixed to the lower surface 110b of the insulating base material 110 is accommodated in and bonded to the recess portion 131 formed on the metal plate 130, so that a gap between the metal plate 130 and the insulating base material 110 is reduced and the semiconductor device 100 accordingly becomes thinner. Moreover, an example of the conductive bonding member 121 includes, in addition to solder paste, silver (Ag) paste.

The sealing resin 140 is, for example, an insulation property resin, such as a thermosetting epoxy-based resin; is filled between the insulating base material 110 and the metal plate 130; and covers the electronic component 120. Furthermore, the sealing resin 140 covers the side surface of the insulating base material 110 extending to the side surface of the insulating base material 110. The side surface of the insulating base material 110 is covered by the sealing resin 140, which makes it possible to prevent moisture intrusion from the side surface of the insulating base material 110. Consequently, it is possible to prevent the electronic component 120 from being damaged caused by water absorbed by the insulating base material 110. Furthermore, some of the sealing resin 140 is filled in the through-hole 112 that passes through the insulating base material 110 and the adhesive layer 111. As a result of some of the sealing resin 140 being filled in the through-hole 112, adhesion between the sealing resin 140, and the insulating base material 110 and the adhesive layer 111 is improved by the anchor effect.

The wiring layer 150 is formed on the upper surface 110a of the insulating base material 110. The wiring layer 150 is electrically connected to the electronic component 120 by a via 151 that passes through the insulating base material 110 and the adhesive layer 111. The wiring layer 150 and the via 151 are forms by performing electrolytic copper plating using, for example, copper or a copper alloy. The thickness of the wiring layer 150 (the thickness of a portion other than the via 151) may be set to, for example, about 25 μm to 300 μm.

An upper surface of the wiring layer 150 and a part of a side surface of the wiring layer 150 are exposed from the sealing resin 140. As a result of the upper surface of the wiring layer 150 and the part of the side surface of the wiring layer 150 being exposed from the sealing resin 140, heat generated from the electronic component 120 is conducted to the wiring layer 150 by way of the via 151, and is efficiently radiated from the upper surface of the wiring layer 150 and the part of the side surface of the wiring layer 150.

on the upper surface of the wiring layer 150 exposed from the sealing resin 140, a surface treatment layer 171 (one example of a first surface treatment layer) is formed. The surface treatment layer 171 is a plating layer in which a nickel (Ni) layer, a palladium (Pd) layer, and a gold (Au) layer are sequentially laminated in this order. The surface treatment layer 171 is able to be formed by using, for example, an electrolytic plating method or an electroless plating method. The surface treatment layer 171 used may be a Ni/Au layer or an Au layer, instead of the Ni/Pd/Au layer. As a result of the surface treatment layer 171 being formed on the upper surface of the wiring layer 150, it is possible to enhance the solder wetting characteristics with respect to the upper surface of the wiring layer 150.

The electrolytic copper plating layer 160 covers the lower surface 130b of the metal plate 130 exposed from the sealing resin 140. The electrolytic copper plating layer 160 is formed by using the same metal material as that used for the wiring layer 150 and the via 151, that is, formed by using copper or a copper alloy. The electrolytic copper plating layer 160 is formed at the same time as when, for example, the electrolytic copper plating layer and the via 151 constituting the wiring layer 150 are formed by performing electrolytic copper plating. The thickness of the electrolytic copper plating layer 160 may be set to, for example, about 25 μm to 300 μm.

In the embodiment, as a result of the electrolytic copper plating layer 160 covering the lower surface 130b of the metal plate 130, it is possible to practically increase the thickness of the metal plate 130 by an amount corresponding to the thickness of the electrolytic copper plating layer 160. Accordingly, in addition to conduction of heat to the metal plate 130 in the thickness direction, it is possible to facilitate dispersion of heat in the surface direction of the metal plate 130 (in the direction perpendicular to the thickness direction). As a result of this, it is possible to improve the heat radiation efficiency of the semiconductor device 100.

A surface treatment layer 172 (one example of a second surface treatment layer) is formed on the lower surface of the electrolytic copper plating layer 160. The surface treatment layer 172 is a plating layer made of the same metal material as that used for the surface treatment layer 171, and is a plating layer in which, similarly to the surface treatment layer 171, a Ni layer, a Pd layer, and an Au layer are sequentially laminated in this order. The surface treatment layer 172 is formed at the same time when the surface treatment layer 171 is formed by using, for example, an electrolytic plating method or an electroless plating method. The surface treatment layer 172 used may be a Ni/Au layer or an Au layer, instead of the Ni/Pd/Au layer. As a result of the surface treatment layer 172 being formed on the lower surface of the electrolytic copper plating layer 160, it is possible to enhance the solder wetting characteristics with respect to the lower surface of the electrolytic copper plating layer 160.

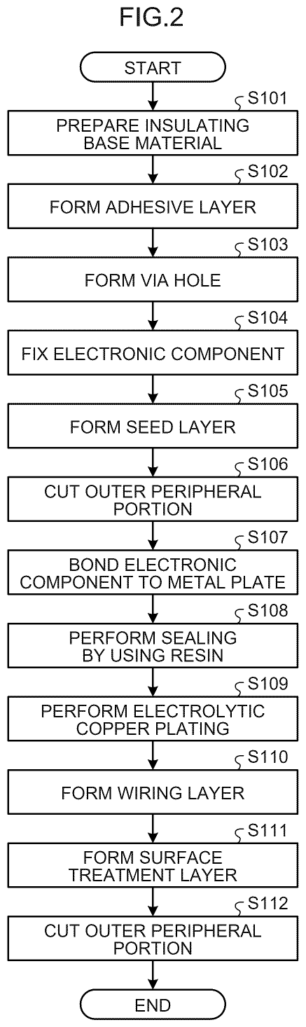

In the following, a method of manufacturing the semiconductor device 100 that is constituted as described above will be described with reference to FIG. 2 by using specific examples. FIG. 2 is a flowchart illustrating the method of manufacturing the semiconductor device 100 according to the embodiment.

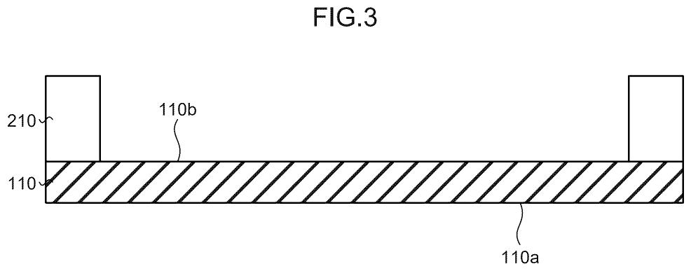

First, the insulating base material 110 is prepared (Step S101). Specifically, as illustrated in, for example, FIG. 3, a support frame 210 having a rectangular shape is fixed to the lower surface 110b of the insulating base material 110. FIG. 3 is a diagram illustrating a specific example of the insulating base material. The material used for the insulating base material 110 may be, for example, an insulation property resin, such as a polyimide-based resin, a polyethylene-based resin, or an epoxy-based resin.

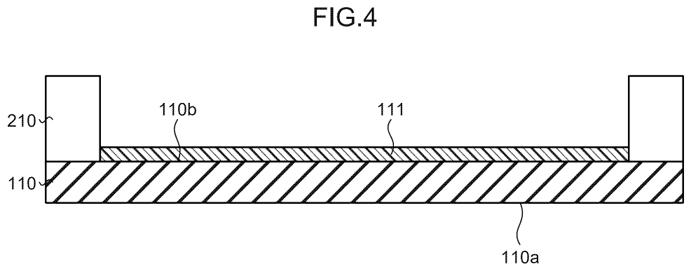

Subsequently, the adhesive layer 111 is formed on the lower surface 110b of the insulating base material 110 (Step S102). Specifically, as illustrated in, for example, FIG. 4, in an area surrounded by the support frame 210, the adhesive layer 111 that is in a semi cured state is formed on the lower surface 110b of the insulating base material 110 by using, for example, a spin coating technique. FIG. 4 is a diagram illustrating a specific example of an adhesive layer forming process. The material used for the adhesive layer 111 may be, for example, a thermosetting resin, such as an epoxy-based resin, a polyimide-based resin, or a silicon-based resin.

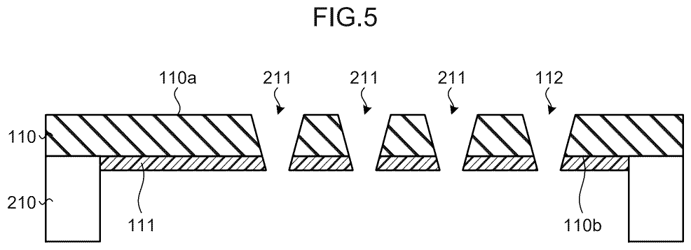

Subsequently, a via hole is formed in the insulating base material 110 and the adhesive layer 111 (Step S103). Specifically, in the area in which the wiring layer 150 (see FIG. 1) is to be formed, as illustrated in, for example FIG. 5, a via hole 211 passing through the insulating base material 110 and the adhesive layer 111 in the thickness direction is formed. At this time, the through-hole 112 passing through the insulating base material 110 and the adhesive layer 111 in the thickness direction at the position that is not overlapped with the position of the wiring layer 150 is formed in a manner adjacent to the via hole 211. FIG. 5 is a diagram illustrating a specific example of a via hole forming process. Each of the via hole 211 and the through-hole 112 has a tapered shape in which the diameter of each of the via hole 211 and the through-hole 112 decreases as each of the via hole 211 and the through-hole 112 is away from the upper surface 110a of the insulating base material 110. Each of the via hole 211 and the through-hole 112 is able to be formed by performing, for example, laser beam machining or punching processing.

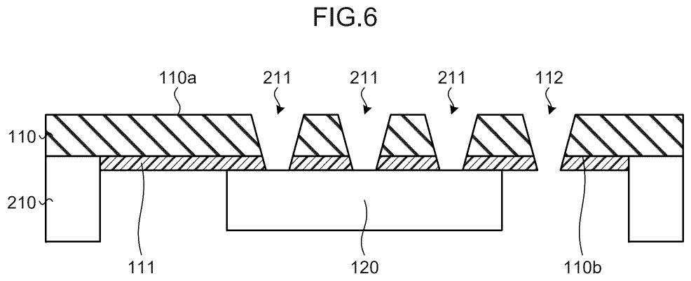

Subsequently, at the position of the via hole 211, the electronic component 120 is fixed to the lower surface 110b of the insulating base material 110 by way of the adhesive layer 111 (Step S104). Specifically, as illustrated in, for example, FIG. 6, the electronic component 120 is bonded to the lower surface 110b of the insulating base material 110 by way of the adhesive layer 111, and an electrode (not illustrated) of the electronic component 120 is exposed on the bottom of the via hole 211. When the electronic component 120 is adhered to the lower surface 110b of the insulating base material 110 by way of the adhesive layer 111, the adhesive layer 111 is thermally cured. FIG. 6 is a diagram illustrating a specific example of an electronic component fixing process.

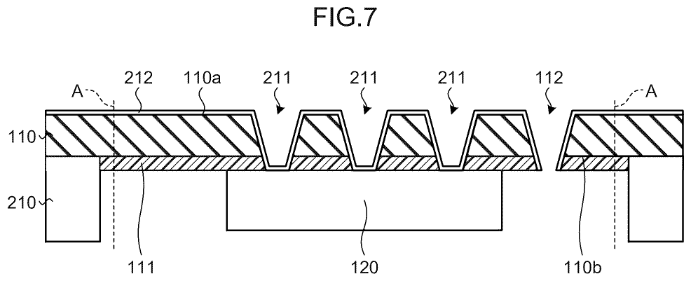

When the electronic component 120 is fixed, a seed layer is formed on the upper surface 110a of the insulating base material 110 (Step S105). Specifically, as illustrated in, for example, FIG. 7, a seed layer 212 that continuously covers the upper surface 110a of the insulating base material 110, the inner surface of the via hole 211, and the electrode (not illustrated) of the electronic component 120 exposed on the bottom of the via hole 211 is formed. At this time, the seed layer 212 is also formed in the interior of the through-hole 112. FIG. 7 is a diagram illustrating a specific example of a seed layer forming process. The process of forming the seed layer 212 is performed by using, for example, a sputtering method or an electroless plating method. The material used for the seed layer 212 may be, for example, copper (Cu), or the like. The thickness of the seed layer 212 may be set to, for example, about 10 nm to 1000 nm.

Furthermore, an adhesion layer may also be formed below the seed layer 212 as needed. A process of forming the adhesion layer is performed by using the sputtering method or the electroless plating method. The material used for the adhesion layer may be, for example, titanium, or the like. As a result of the adhesion layer being formed below the seed layer 212, adhesion of the seed layer 212 with respect to the upper surface 110a of the insulating base material 110 is improved. The thickness of the adhesion layer may be set to, for example, about 10 nm to 500 nm.

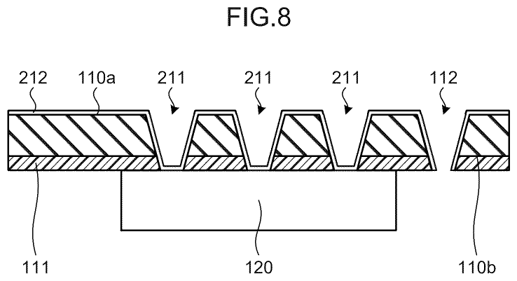

When the seed layer 212 has been formed, the outer peripheral portion of each of the insulating base material 110 and the adhesive layer 111 is cut by performing a dicing process (Step S106). Specifically, at a cutting line A (see FIG. 7) passing through the inner side of the support frame 210, the outer peripheral portion of each of the insulating base material 110 and the adhesive layer 111 is cut by, for example, a dicer or a slicer. As a result of this, as illustrated in, for example, FIG. 8, the support frame 210 is cut off from each of the insulating base material 110 and the adhesive layer 111. FIG. 8 is a diagram illustrating a specific example of an outer peripheral portion cutting process.

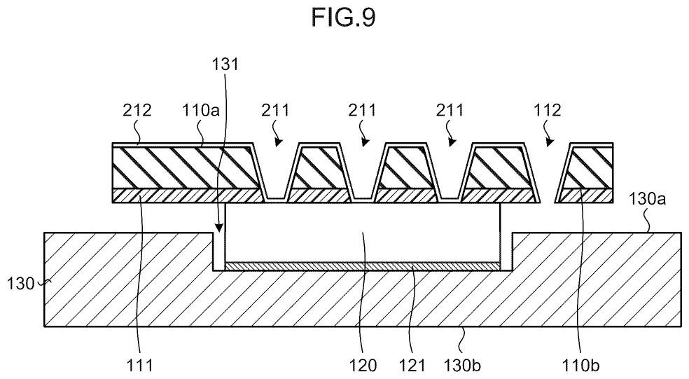

When the support frame 210 has been cut off, the electronic component 120 that is fixed on the lower surface 110b of the insulating base material 110 is bonded to the metal plate 130 (Step S107). Specifically, first, the metal plate 130 in which the recess portion 131 is formed on the upper surface 130a is prepared. Then, the electronic component 120 is accommodated in the recess portion 131 formed on the metal plate 130, and is bonded to the bottom surface of the recess portion 131 by way of the conductive bonding member 121 constituted by, for example, solder paste, or the like. As a result of this, as illustrated in, for example, FIG. 9, the intermediate structure in which the electronic component 120 is sandwiched by the insulating base material 110 and the metal plate 130 is formed. FIG. 9 is a diagram illustrating a specific example of a bonding process.

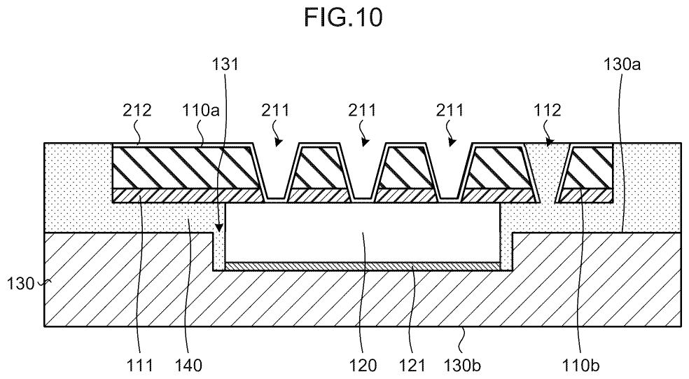

The intermediate structure is subjected to resin sealing by forming, for example, transfer molding (Step S108). In other words, the intermediate structure is accommodated in the metal mold, the sealing resin 140 that is an unsecured state is injected into the metal mold. Then, the sealing resin 140 is heated to a predetermined temperature and hardened. As the resin sealing method, in addition to the transfer molding technique, for example, a compression molding technique, an injection molding technique, and the like may be used. As a result of the intermediate structure being subjected to resin sealing, as illustrated in, for example, FIG. 10, the sealing resin 140 is filled in a gap between the insulating base material 110 and the metal plate 130, and the electronic component 120 is sealed. Furthermore, the sealing resin 140 extends to the side surface of the insulating base material 110, and thus, the side surface of the insulating base material 110 is sealed. Furthermore, some of the sealing resin 140 is filled in the through-hole 112 that passes through the insulating base material 110 and the adhesive layer 111. FIG. 10 is a diagram illustrating a specific example of a resin sealing process.

When the intermediate structure has been subjected to the resin sealing, electrolytic copper plating is performed on both of the upper surface 110a of the insulating base material 110 exposed from the sealing resin 140 and the lower surface 130b of the metal plate 130 exposed from the sealing resin 140 (Step S109). In other words, a resist layer is formed on the side surface of the metal plate 130, and power is supplied from both of the seed layer 212 and the metal plate 130, so that the electrolytic copper plating is performed on the entire surface of the intermediate structure. At this time, the lower surface 130b of the metal plate 130 is not covered by the resist layer, so that electrolyte copper is deposited to the lower surface 130b of the metal plate 130, as well as the upper surface 110a of the insulating base material 110 and the via hole 211.

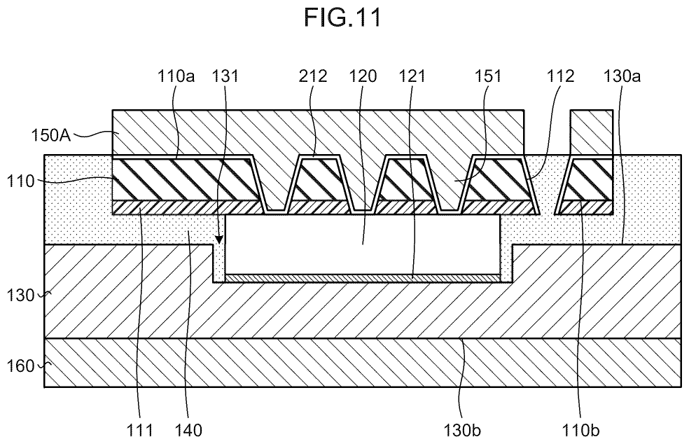

In other words, as illustrated in, for example, FIG. 11, an electrolytic copper plating layer 150A (one example of the metal layer disposed on the other of the surfaces of the insulating base material) is formed on the upper surface 110a of the insulating base material 110, and the via 151 is formed by electrolyte copper being filled into the via hole 211. Then, at the same time when the electrolytic copper plating layer 150A and the via 151 are formed, the electrolytic copper plating layer 160 is formed on the lower surface 130b of the metal plate 130. Therefore, the lower surface 130b of the metal plate 130 is covered by the electrolytic copper plating layer 160. FIG. 11 is a diagram illustrating a specific example of an electrolytic copper plating process. After having performed electrolytic copper plating, the resist layer that covers the side surface of the metal plate 130 is removed.

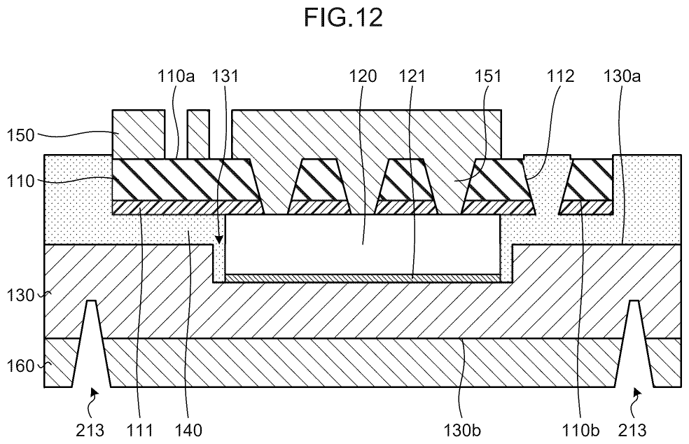

Then, the wiring layer 150 having a desired wiring pattern is formed from the electrolytic copper plating layer 150A (Step S110). The wiring layer 150 is formed from the electrolytic copper plating layer 150A by using, for example, a subtractive method. In other words, a resist layer that covers a portion remaining as a wiring pattern is formed on the upper surface of the electrolytic copper plating layer 150A. Then, the electrolytic copper plating layer 150A that is exposed without being covered by the resist layer is removed by an etching process. As a result of this, as illustrated in, for example, FIG. 12, the wiring layer 150 that has a desired wiring pattern and that is connected to the electronic component 120 by way of the via 151 is formed. FIG. 12 is a diagram illustrating a specific example of a wiring layer forming process. A part of each of the upper surface and the side surface of the wiring layer 150 is exposed from the sealing resin 140. When the wiring layer 150 has been formed, the resist layer is removed, the seed layer 212 disposed at the portion that is not covered by the wiring layer 150 is removed by a flash etching process by using the wiring layer 150 as a mask. Moreover, the seed layer 212 that is in contact with both of the wiring layer 150 and the via 151, and the seed layer 212 that is located in the interior of the through-hole 112 remain after the flash etching process has been performed; however, this state is not illustrated in FIG. 12.

When the seed layer 212 has been removed, a groove is formed in the outer peripheral portion of the metal plate 130 and the electrolytic copper plating layer 160. In other words, a resist layer having an opening is formed, on the lower surface of the electrolytic copper plating layer 160, at a position in which the groove is to be formed. Then, the outer peripheral portion of the metal plate 130 and the electrolytic copper plating layer 160 corresponding to a position of the opening of the resist layer is removed by performing a half etching process, so that a pair of grooves 213 is formed in the outer peripheral portion of the metal plate 130 and the electrolytic copper plating layer 160. Each of the grooves 213 has a tapered shape in which the width is gradually reduced in the depth direction.

Subsequently, for example, by using an electroless plating method, the surface treatment layer 171 that covers the upper surface of the wiring layer 150 is formed, and the surface treatment layer 172 that covers the lower surface of the electrolytic copper plating layer 160 is also formed (Step S111).

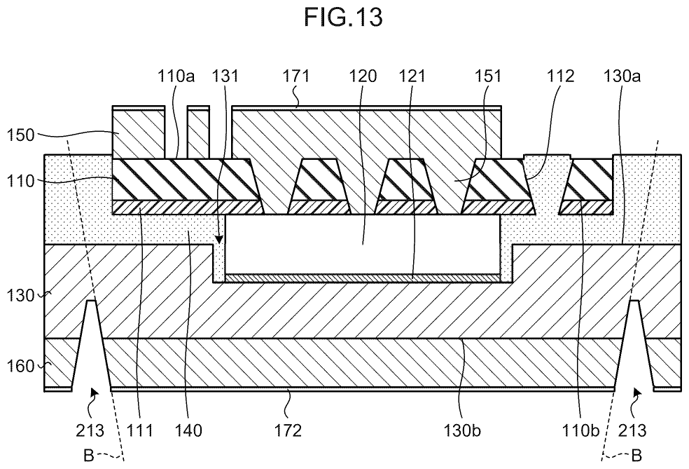

By performing the processes described up to here, as illustrated in, for example FIG. 13, a structure having the same structure of the semiconductor device 100 is obtained. FIG. 13 is a diagram illustrating a specific example of a surface treatment layer forming process. After that, the outer peripheral portion of the structure illustrated in FIG. 13 is cut by using a dicing process (Step S112). Specifically, at a cutting line B along the side surface of the groove 213 that has a tapered shape, the outer peripheral portion of each of the electrolytic copper plating layer 160, the metal plate 130, and the sealing resin 140 is cut by, for example, a dicer or a slicer, and, as a result of this, the semiconductor device 100 is obtained.

At this time, as a result of the outer peripheral portion of each of the electrolytic copper plating layer 160, the metal plate 130, and the sealing resin 140 being cut along the side surface of the groove 213 having the tapered shape, the side surface of each of the electrolytic copper plating layer 160, the metal plate 130, and the sealing resin 140 becomes a side surface having a tapered shape when viewed from the side. Therefore, the metal plate 130 has a tapered shape in which the width of the lower surface 130b that is exposed from the sealing resin 140 is smaller than the width of the upper surface 130a that is covered by the sealing resin 140. As a result of this, the size of the bottom surface of the semiconductor device 100 is reduced, and, when the semiconductor device 100 is packaged on the mounting substrate, it is possible to perform positional alignment between the pad disposed on the mounting substrate and the bottom surface of the semiconductor device 100 with high accuracy.

Moreover, the outer peripheral portion cutting process performed at Step S112 may be omitted as needed. In this case, the side surfaces of the electrolytic copper plating layer 160, the metal plate 130, and the sealing resin 140 become a linear side surface in a lateral view.

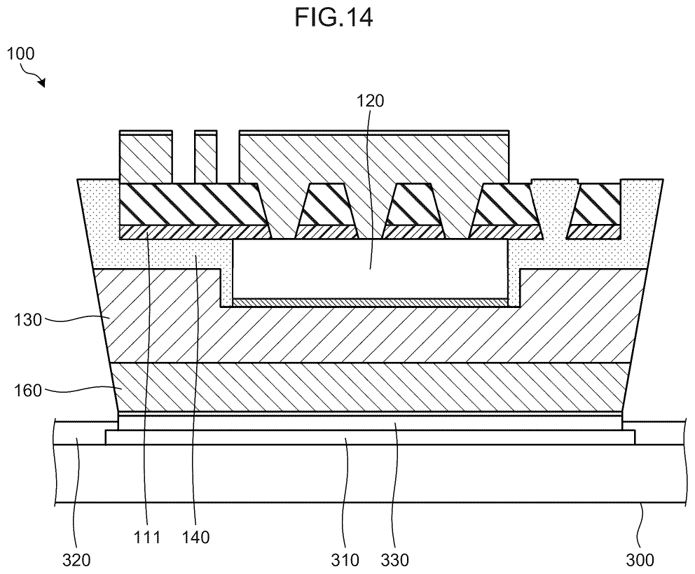

The semiconductor device 100 obtained by being cut is able to mount on a mounting substrate. Specifically, it is possible to mount the semiconductor device 100 on the mounting substrate by using both of the metal plate 130 and the electrolytic copper plating layer 160 as terminals. FIG. 14 is a diagram illustrating a mounting process of the semiconductor device 100.

As illustrated in FIG. 14, a pad 310 is formed in the wiring layer disposed on the upper surface of a mounting substrate 300, and the pad 310 is exposed from the opening portion of a solder resist layer 320. When the semiconductor device 100 is mounted on the mounting substrate 300, positional alignment between the electrolytic copper plating layer 160 and the pad 310 disposed on the mounting substrate 300 with respect to the bottom surface of the semiconductor device 100 is performed. Then, the electrolytic copper plating layer 160 and the pad 310 are bonded by a solder 330. At this time, the metal plate 130 has a tapered shape, so that the size of the electrolytic copper plating layer 160 disposed below the metal plate 130 is reduced, and it is thus possible to perform the positional alignment between the electrolytic copper plating layer 160 and the pad 310 with high accuracy.

In the state illustrated in FIG. 14, the heat generated from the electronic component 120 is conducted to the electrolytic copper plating layer 160 via the metal plate 130, and is radiated from the electrolytic copper plating layer 160 by way of the solder 330 and the pad 310. In other words, in addition to the heat being conducted in the thickness direction of the metal plate 130, it is possible to facilitate dispersion of heat in a surface direction of the metal plate 130 (in the direction perpendicular to the thickness direction) in the electrolytic copper plating layer 160, and, as a result of this, it is possible to improve the heat radiation efficiency of the semiconductor device 100.

As described above, the semiconductor device (as one example, the semiconductor device 100) according to the embodiment includes the insulating base material (as one example, the insulating base material 110), the electronic component (as one example, the electronic component 120), the metal plate (as one example, the metal plate 130), sealing resin (as one example, the sealing resin 140), the wiring layer (as one example, the wiring layer 150), and the metal layer (as one example, the electrolytic copper plating layer 160). The insulating base material includes the adhesive layer (as one example, the adhesive layer 111) on one of the surfaces (as one example, the lower surface 110b) of the insulating base material. The electronic component is fixed to one of the surfaces of the insulating base material by way of the adhesive layer. The metal plate is arranged so as to sandwich the electronic component with one of the surfaces of the insulating base material. The sealing resin is filled between the insulating base material and the metal plate, and covers the electronic component. The wiring layer is formed on the other of the surfaces (as one example, the upper surface 110a) of the insulating base material, and is connected to the electronic component by way of the via (as one example, the via 151) that passes through the insulating base material and the adhesive layer. The metal layer is made of the same metal material as that used for the wiring layer, and covers the surface (as one example, the lower surface 130b) of the metal plate located on a side opposite to the surface (as one example, the upper surface 130a) that is covered by the sealing resin. As a result of this, it is possible to improve the heat radiation efficiency.

According to an aspect of an embodiment of the semiconductor device disclosed in the present application, an advantage is provided in that it is possible to improve heat radiation efficiency.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
an insulating base material that includes an adhesive layer on one of surfaces of the insulating base material;
an electronic component that is fixed to the one of the surfaces of the insulating base material by way of the adhesive layer;
a metal plate that is arranged so as to sandwich the electronic component with the one of the surfaces of the insulating base material;
a sealing resin that is filled between the insulating base material and the metal plate, and that covers the electronic component;
a wiring layer that is formed on another of the surfaces of the insulating base material, and that is connected to the electronic component by way of a via that passes through the insulating base material and the adhesive layer; and
a metal layer that is made of a same metal material as that used for the wiring layer and the via, and that covers a surface of the metal plate located on a side opposite to a surface that is covered by the sealing resin.

2. The semiconductor device according to claim 1, wherein an upper surface of the wiring layer and a part of a side surface of the wiring layer are exposed from the sealing resin.

3. The semiconductor device according to claim 2, further comprising
a first surface treatment layer that covers the upper surface of the wiring layer exposed from the sealing resin, and
a second surface treatment layer that is made of a same metal material as that used for the first surface treatment layer, and that covers a surface of the metal layer located on a side opposite to a surface that is in contact with the metal plate.

4. The semiconductor device according to claim 1, wherein the insulating base material includes a side surface that is joined to the one of the surfaces of the insulating base material and the other of the surfaces of the insulating base material, and that is covered by the sealing resin.

5. The semiconductor device according to claim 1, wherein the metal plate has a tapered shape in which a width of the surface of the metal plate located on the side opposite to the surface that is covered by the sealing resin is smaller than a width of the surface that is covered by the sealing resin.

6. The semiconductor device according to claim 1, wherein
the metal plate includes a recess portion, on the surface that is covered by the sealing resin, at a position corresponding to a position of the electronic component, and
the electronic component is accommodated in the recess portion, and is bonded to a bottom surface of the recess portion.

7. The semiconductor device according to claim 1, wherein
the insulating base material and the adhesive layer include a through-hole that passes through the insulating base material and the adhesive layer in a thickness direction at a position that does not overlap with a position of the wiring layer, and
a part of the sealing resin is filled in the through-hole.

8. A method of manufacturing a semiconductor device, the method comprising:
forming an adhesive layer on one of surfaces of an insulating base material;
forming a via hole that passes through the insulating base material and the adhesive layer;
fixing an electronic component to the one of the surfaces of the insulating base material at a position of the via hole by way of the adhesive layer;
arranging a metal plate so as to sandwich the electronic component with the one of the surfaces of the insulating base material, and bonding the electronic component to the metal plate;
covering the electronic component by filling a sealing resin between the insulating base material and the metal plate;
forming, by performing plating using a metal material, a metal layer on another of the surfaces of the insulating base material and a via in the via hole, the via connecting the metal layer and the electronic component;
forming, in parallel with the forming the metal layer and the via, a metal layer that is made of the metal material and that covers a surface of the metal plate located on a side opposite to a surface that is in contact with the sealing resin; and
forming a wiring layer that is connected to the electronic component by way of the via by performing etching on the metal layer located on the other of the surfaces of the insulating base material.
